(19) United States
(12) Patent Application Publication
(10) Pub. No.: US 2026/0182249 A1
(43) Pub. Date: Jun. 25, 2026

(54) THERMOELECTRIC STACK AND THERMOELECTRIC DEVICE

(71) Applicant: NATIONAL INSTITUTE FOR MATERIALS SCIENCE, Tsukuba-shi (JP)

(72) Inventors: Fuyuki ANDO, Ibaraki (JP); Yasuyuki OIKAWA, Ibaraki (JP); Kenichi UCHIDA, Ibaraki (JP)

(21) Appl. No.: 19/539,854

(22) Filed: Feb. 13, 2026

Related U.S. Application Data
(63) Continuation of application No. PCT/JP2024/029879, filed on Aug. 22, 2024.

(30) Foreign Application Priority Data
Sep. 19, 2023 (JP) 2023-150837

(51) Int. Cl. H10N 10/81; H10N 10/13

(52) U.S. Cl. CPC H10N 10/81; H10N 10/13

(57) ABSTRACT

To provide a thermoelectric device for easy positioning and bonding processes and a thermoelectric stack for such device. A representative embodiment of the present invention is a thermoelectric stack comprising a thermoelectric material layer having a first surface and a second surface opposite each other and an isolation layer stacked on the first surface of the thermoelectric material layer, wherein the thermoelectric material layer has a magnetization component perpendicular to the first surface and the second surface, and the isolation layer comprises, when a second thermoelectric stack is stacked on the surface opposite to the surface on which the thermoelectric material layer is to be stacked, an insulation region that electrically insulates the thermoelectric material layer and an electrode region that electrically conducts the thermoelectric material layer. Also, a representative embodiment of the present invention is a thermoelectric device in which such thermoelectric stacks are stacked, wherein a plurality of first thermoelectric stacks in which thermoelectric material layers have positive transverse thermoelectric power and a plurality of second thermoelectric stacks in which thermoelectric material layers have negative transverse thermoelectric power are alternately brought into close contact with each other due to the magnetic force of their magnetized components, interposing their respective isolation layers, and are electrically connected by electrode regions of the isolation layers.

### TECHNICAL FIELD

The present invention relates to a thermoelectric stack and a thermoelectric device.

### BACKGROUND ART

To improve the efficiency of energy use, it is desirable to commercialize thermoelectric conversion devices that can generate electricity from waste heat and the environment. As the development of thermoelectric materials with high conversion efficiency progresses, many π-type structures have been proposed in which p-type and n-type thermoelectric materials are alternately connected in series to obtain a high electromotive force as a power generation device.

PTL 1 discloses a thermoelectric element in which thermal electromotive force layers made of a first thermoelectric material and conductive layers made of a second thermoelectric material are alternately stacked, each having an insulation layer interposed therebetween. It is believed that a thermoelectric element with improved thermoelectric performance can be realized by making the absolute value of the Seebeck coefficient of the first thermoelectric material constituting the thermal electromotive force layer larger than the absolute value of the Seebeck coefficient of the second thermoelectric material constituting the conductive layer, making the conductivity of the first thermoelectric material smaller than that of the second thermoelectric material, and providing an insulation layer between the thermal electromotive force layer and the conductive layer.

PTL 2 proposes a structure in which a transverse thermoelectric material with magnetization perpendicular to the surface is electrically connected to a longitudinal thermoelectric material via an insulation layer. It is believed that a new thermoelectric conversion element can be realized that can increase the thermoelectric power generated in a direction perpendicular to both the temperature gradient and magnetization while maintaining the thermoelectric conversion properties of the magnetic material.

PTL 3 proposes a thin film stacked structure of a ferromagnetic film/insulator film/thermoelectric material film/insulator film/ferromagnetic film formed on a substrate. It is believed that it will be possible to realize a thermoelectric conversion device that is small but can generate a large electromotive force.

### CITATION LIST

### Patent Document

PTL 1: Japanese Patent Application Laid-Open No. 2016-213455

PTL 2: International Publication WO2021/187347A1

PTL 3: Japanese Patent Application Laid-Open No. 2020-098860

### SUMMARY OF THE INVENTION

### Problems to be Solved by the Invention

Conventional π-type thermoelectric modules are formed by stacking block-shaped p-type and n-type thermoelectric materials and electrodes connecting the thermoelectric materials in three dimensions while precisely positioning them, and then bonding them together using processes such as pressure and heat. This requires highly accurate positioning and process control technology.

An object of the present invention is to provide a thermoelectric device for easy positioning and bonding processes and a thermoelectric stack for such device.

Means for solving these problems will be described below; other issues and novel features will become apparent from this specification and the accompanying drawings.

### Means for Solving Problems

According to a first embodiment, the following is true.

The first embodiment of the present invention is a thermoelectric stack comprising a thermoelectric material layer having a first surface and a second surface opposite each other and an isolation layer stacked on the first surface of the thermoelectric material layer, wherein the thermoelectric material layer has a magnetization component perpendicular to the first surface and the second surface, and wherein the isolation layer comprises, when a second thermoelectric stack is stacked on the surface opposite to the surface on which the thermoelectric material layer is to be stacked, an insulation region that electrically insulates the thermoelectric material layer from a thermoelectric material layer of the second thermoelectric stack and an electrode region that electrically connects the thermoelectric material layer to a thermoelectric material layer of the second thermoelectric stack.

According to a second embodiment, the following is true.

That is, the second embodiment of the present invention is the thermoelectric stack described in the first embodiment, wherein the isolation layer extends from an end of the first surface to a side surface of the thermoelectric material layer, and has the electrode region in the extended region.

According to a third embodiment, the following is true.

That is, the third embodiment of the present invention is the thermoelectric stack described in the first embodiment, wherein the electrode region of the isolation layer is interposed between the thermoelectric material layer and the thermoelectric material layer of the second thermoelectric stack when the second thermoelectric stack is stacked on the surface opposite the surface on which the thermoelectric material layer is stacked.

According to a fourth embodiment, the following is true.

That is, the fourth embodiment of the present invention is the thermoelectric stack described in any of the first through third embodiments, wherein the thermoelectric material layer has a three-dimensional shape that engages with the isolation layer on a surface in contact with the isolation layer.

According to a fifth embodiment, the following is true.

That is, the fifth embodiment of the present invention is the thermoelectric stack described in any of the first through fourth embodiments, wherein the isolation layer is a first isolation layer, the insulation region is a first insulation region, and the electrode region is a first electrode region, the thermoelectric stack has a second isolation layer stacked on the second surface, and the second isolation layer comprises, when a second thermoelectric stack is stacked due to the magnetic force of the magnetization component on the surface opposite to the surface on which the thermoelectric material layer is to be stacked, a second insulation region that electrically insulates the thermoelectric material layer from the second thermoelectric stack and a second electrode region that electrically connects the thermoelectric material layer to a thermoelectric material layer of the second thermoelectric stack.

According to a sixth embodiment, the following is true.

That is, the sixth embodiment of the present invention is the thermoelectric stack described in the fifth embodiment, wherein the first electrode region and the second electrode region are positioned apart from each other in the plane of the first and second surfaces when the first and second surfaces are viewed in plan view.

According to a seventh embodiment, the following is true.

That is, the seventh embodiment of the present invention is the thermoelectric stack described in the third embodiment, wherein the insulation region is adhesive.

According to an eighth embodiment, the following is true.

That is, the eighth embodiment of the present invention is the thermoelectric stack described in the seventh embodiment, wherein the insulation region is removable.

According to a ninth embodiment, the following is true.

That is, the ninth embodiment of the present invention is the thermoelectric stack described in any of the first through eighth embodiments, wherein the thermoelectric material layer comprises two or more thermoelectric materials.

According to a tenth embodiment, the following is true.

That is, the tenth embodiment of the present invention is the thermoelectric stack described in the ninth embodiment, wherein the thermoelectric material layer is formed by stacking unit thermoelectric material layers of the two or more thermoelectric materials.

According to an eleventh embodiment, the following is true.

That is, in the eleventh embodiment of the present invention, one or more first thermoelectric stacks as described in any one of the first through tenth embodiments, the thermoelectric material layers of which have positive transverse thermoelectric power and one or more second thermoelectric stacks as described in any of the first to tenth embodiments, the thermoelectric material layers of which have negative transverse thermoelectric power are alternately brought into close contact with each other due to the magnetic force of their magnetized components, interposing their respective isolation layers, and are electrically connected by electrode regions of the isolation layers.

According to a twelfth embodiment, the following is true.

That is, the twelfth embodiment of the present invention is the thermoelectric device described in the eleventh embodiment, wherein the thermoelectric material of the first thermoelectric stack is a magnetic material mainly composed of at least one material selected from the group consisting of samarium-cobalt (Sm-Co) alloy, cobalt-manganese gallium (Co₂MnGa) alloy, cobalt-manganese aluminum/silicon (Co₂Mn (Al, Si)) alloy, cobalt (Co), iron-gallium (Fe—Ga) alloy, iron-aluminum (Fe—Al) alloy, iron-platinum (FePt) alloy, iron-lead (FePd) alloy, iron-tin (Fe₃Sn₂) alloy, and iron nitride (Fe₄N), and the thermoelectric material of the second thermoelectric stack is a magnetic material mainly composed of at least one material selected from the group consisting of neodymium iron boron (NdFeB) alloy, manganese gallium (MnGa) alloy, iron (Fe), and cobalt-gadolinium (Co—Gd) alloy.

According to a thirteenth embodiment, the following is true.

That is, the thirteenth embodiment of the present invention is a thermoelectric device in which one or more first thermoelectric material layers having positive transverse thermoelectric power and one or more second thermoelectric material layers having negative transverse thermoelectric power are alternately stacked with an isolation layer interposed therebetween, the first and second thermoelectric material layers have magnetization components in the same direction perpendicular to the plane in which they are stacked, and the isolation layer comprises an insulation region that electrically insulates the first and second thermoelectric material layers that are in close contact with each other due to the magnetic force of the magnetization component, and an electrode region that conducts the first and second thermoelectric material layers together, and the electrode regions in contact with both surfaces of the first and second thermoelectric material layers are arranged at positions spaced apart from each other in a direction perpendicular to both the stacking direction of the thermoelectric material layers and the direction in which a temperature gradient is applied.

According to a fourteenth embodiment, the following is true.

That is, the fourteenth embodiment of the present invention is the thermoelectric device described in the thirteenth embodiment, wherein the isolation layer extends from an end of the surface to be stacked to the side surface of the thermoelectric material layer and has the electrode region in the extended region.

According to a fifteenth embodiment, the following is true.

That is, the fifteenth embodiment of the present invention is the thermoelectric device described in the thirteenth embodiment, wherein the first thermoelectric material layer and the second thermoelectric material layer adjacent to each other are removably stacked with the isolation layer interposed therebetween due to the magnetic force of the magnetization component.

According to a sixteenth embodiment, the following is true.

That is, the sixteenth embodiment of the present invention is the thermoelectric device described in any of the thirteenth through fifteenth embodiments, wherein the first and second thermoelectric material layers have a three-dimensional shape that engages with the isolation layer on at least one side that is in contact with the electrode region of the isolation layer.

According to a seventeenth embodiment, the following is true.

That is, the seventeenth embodiment of the present invention is the thermoelectric device described in any of the thirteenth through sixteenth embodiments, wherein the first thermoelectric material is a magnetic material mainly composed of at least one material selected from the group consisting of Sm—Co alloy, Co₂MnGa alloy, Co₂Mn (Al, Si) alloy, Co, Fe—Ga alloy, Fe—Al alloy, FePt alloy, FePd alloy, Fe₃Sn₂ alloy, and iron nitride (Fe₄N), and the second thermoelectric material is a magnetic material mainly composed of at least one material selected from the group consisting of NdFeB alloy, MnGa alloy, Fe, and Co—Gd alloy.

According to an eighteenth embodiment, the following is true.

That is, the eighteenth embodiment of the present invention is the thermoelectric device described in any of the thirteenth through sixteenth embodiments, wherein at least one of the first and second thermoelectric material layers is a stack comprising a plurality of thermoelectric material layers that are different from each other.

### Effect of the Invention

The effect to be produced by the above-described embodiment will be briefly described below.

In other words, a thermoelectric device for easy positioning and bonding processes and a thermoelectric stack for such device can be provided.

### BRIEF DESCRIPTION OF THE DRAWINGS

FIG. 1 is an explanatory diagram schematically illustrating a basic configuration of a thermoelectric stack according to the present invention.

FIG. 2 is an explanatory diagram schematically illustrating an operation principle of a thermoelectric device according to the present invention.

FIG. 3 is an explanatory diagram illustrating an example configuration of a thermoelectric device as Example of the present invention.

FIG. 4 is an explanatory drawing illustrating a variation of an electrode region.

FIG. 5 is an explanatory drawing illustrating another variation of an electrode region.

FIG. 6 is an explanatory drawing illustrating another electrode structure.

FIG. 7 is a graph showing the measurement results of the power generation behavior of the thermoelectric material fabricated as Example.

FIG. 8 is a graph showing the power generation performance of the transverse thermoelectric module fabricated as Example.

FIG. 9 is an explanatory diagram illustrating another example configuration of a thermoelectric device according to the present invention.

### DETAILED DESCRIPTION OF THE INVENTION

### 1. Overview of Embodiment

First, an overview of a representative embodiment disclosed in the present application will be given. Reference signs in the drawings that are referred to in parentheses in the outline description of representative embodiment are merely illustrative of what is included in the concept of the components to which they refer.

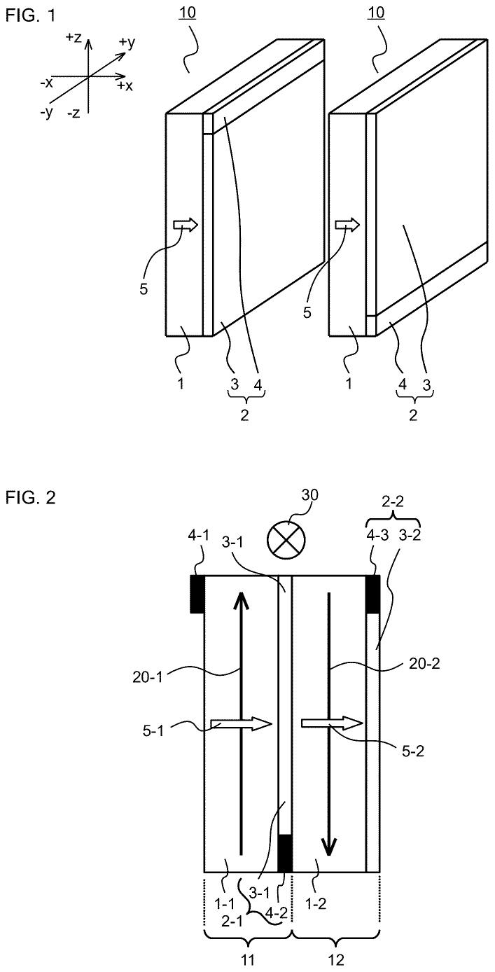

### [1] Thermoelectric Stack Having Magnetization Components Perpendicular to Contact Surface and Electrically Connected at a Part of Isolation Layer (FIG. 1-FIG. 6)

A representative embodiment disclosed in this application is a thermoelectric stack (10) comprising a thermoelectric material layer (1) having a first surface and a second surface opposite each other and an isolation layer (2) stacked on the first surface of the thermoelectric material layer, wherein the thermoelectric material layer has a magnetization component (5) perpendicular to the first surface and the second surface, and the isolation layer comprises, when a second thermoelectric stack is stacked on the surface opposite to the surface on which the thermoelectric material layer is to be stacked, an insulation region (3) that electrically insulates the thermoelectric material layer from a thermoelectric material layer of the second thermoelectric stack and an electrode region (4) that electrically connects the thermoelectric material layer to a thermoelectric material layer of the second thermoelectric stack.

This provides thermoelectric stack for easy positioning and bonding processes for constructing a thermoelectric device.

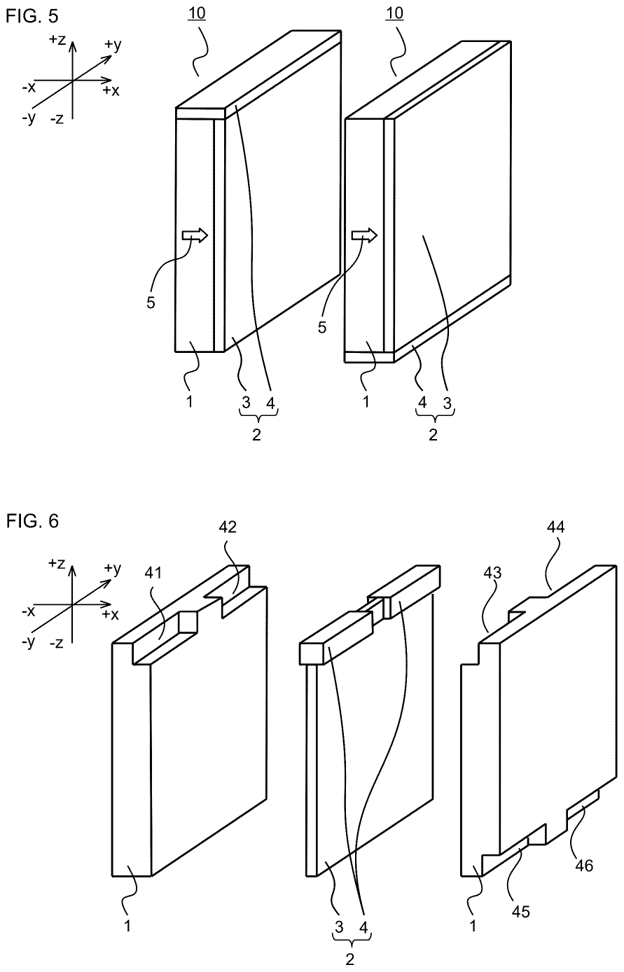

### [2] Electrode Region Extends to Side Surface of Thermoelectric Material Layer (FIG. 4, FIG. 5)

The thermoelectric stack described in [1], wherein the isolation layer extends from an end of the first surface to a side surface of the thermoelectric material layer, and has the electrode region in the extended region.

This allows for greater flexibility in electrode formation and wiring processes. Furthermore, by forming electrode regions (4) at the ends of thermoelectric material layer (1) (for example, FIG. 5), the entire thermoelectric material layer can be configured to contribute to thermoelectric conversion.

### [3] Electrode Region is Region Interposed Between Thermoelectric Material Layers (FIG. 1, FIG. 4).

The thermoelectric stack described in [1], wherein the electrode region of the isolation layer is interposed between the thermoelectric material layer and the thermoelectric material layer of the second thermoelectric stack when the second thermoelectric stack is stacked on the surface opposite the surface on which the thermoelectric material layer is stacked.

This allows the stress due to the magnetic force to be applied directly to the interface between the electrode region and the thermoelectric material layer, resulting in good contact electrical conductivity. Furthermore, the area of the thermoelectric material layer in the area through which the heat flow passes can be maximized. The contribution of the thermoelectric material layer to thermoelectric conversion also depends on the position and area of the electrode region.

[4] Three-Dimensional Structure in Which Thermoelectric Material Layer Engages with Electrode (FIG. 6)

The thermoelectric stack described in any one of [1] to [3], wherein the thermoelectric material layer has a three-dimensional shape that engages with the isolation layer on a surface in contact with the isolation layer.

This allows the thermoelectric material layer and the electrodes to be positioned in a self-aligned manner, making the wiring process even easier.

### [5] Electrically Connected Due to Magnetic Force of Magnetization Component (FIG. 2)

The thermoelectric stack (12) described in any one of [1] to [4], wherein the isolation layer is a first isolation layer (2-2), the insulation region is a first insulation region (3-2), and the electrode region is a first electrode region (4-3), the thermoelectric stack has a second isolation layer (2-1) stacked on the second surface, and the second isolation layer comprises, when a second thermoelectric stack is stacked due to the magnetic force of the magnetization component on the surface opposite to the surface on which the thermoelectric material layer is to be stacked, a second insulation region (3-1) that electrically insulates the thermoelectric material layer from a thermoelectric material layer of the second thermoelectric stack and a second electrode region (4-2) that electrically connects the thermoelectric material layer to a thermoelectric material layer of the second thermoelectric stack.

As a result, electrical connection is formed by close contact due to the magnetic force of the magnetization component of the thermoelectric material layer, and no further wiring process is required.

### [6] Obtaining Electromotive Force by Transverse Thermoelectric Conversion

The thermoelectric stack described in [5], wherein the first electrode region and the second electrode region are positioned apart from each other in the plane of the first and second surfaces when the first and second surfaces are viewed in plan view.

Therefore, by arranging two electrodes at separate positions within the plane of one thermoelectric material layer and applying a temperature gradient in a direction perpendicular to the direction in which they are separated and also perpendicular to the stacking direction, it is possible to extract electromotive force generated in the thermoelectric material layer by transverse thermoelectric conversion between the two electrodes. The first electrode region (4-3) and the second electrode region (4-2) are preferably located on both sides of the thermoelectric material layer (1-2) of the thermoelectric stack (12) in the stacking direction, and are preferably arranged at positions where the potential difference (electromotive force) caused by the driving electric field generated in the direction of the cross product of the applied temperature gradient and the remanent magnetization component is maximized. Here, the first electrode region (4-3) and the second electrode region (4-2) may each be composed of a plurality of electrode regions arranged at positions with approximately the same potential. However, the reference numerals in parentheses are examples adopted by citing FIG. 2, and are not limiting.

### [7] Adhesion

The thermoelectric stack described in [3], wherein the insulation region is adhesive.

This further strengthens the adhesion due to the magnetic force of remanent magnetization.

### [8] Removability

The thermoelectric stack described in [7], wherein the insulation region is removable.

This facilitates easy disassembly of the thermoelectric conversion element composed of this thermoelectric stack.

### [9] Thermoelectric Stack Comprising Two or More Thermoelectric Materials

The thermoelectric stack described in any one of [1] to [8], wherein the thermoelectric material layer comprises two or more thermoelectric materials.

This allows for greater flexibility in the selection of thermoelectric materials.

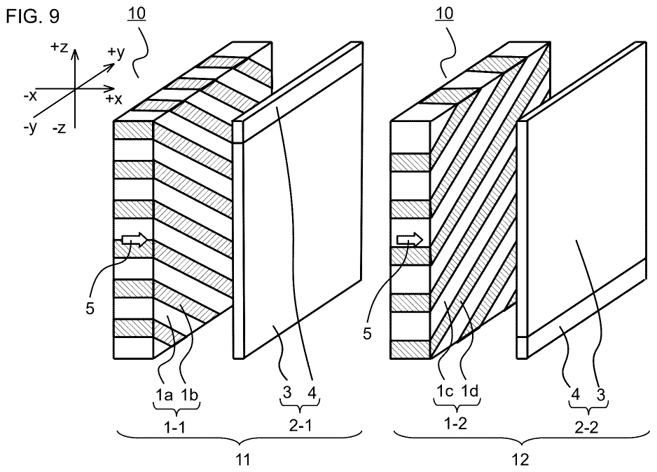

### [10] Tilted Stack (FIG. 9)

The thermoelectric stack described in [9], wherein the thermoelectric material layer is formed by stacking unit thermoelectric material layers of the two or more thermoelectric materials.

This makes it possible to use a transverse thermoelectric material in which p-type and n-type thermoelectric materials are alternately layered with a tilt as the thermoelectric material layer. The “tilted stack” described above is a multilayer structure formed by stacking two or more types of thermoelectric material layers (the “unit thermoelectric material layers” described above), and the “stack” referred to here is different from the “stack” referred to in [1].

### [11] Thermoelectric Device

A representative embodiment disclosed in this application is a thermoelectric device, which comprises: one or more first thermoelectric stacks as described in any one of [1] to [10], the thermoelectric material layers of which have positive transverse thermoelectric power, and one or more second thermoelectric stacks as described in any one of [1] to [10], the thermoelectric material layers of which have negative transverse thermoelectric power are alternately brought into close contact with each other due to the magnetic force of their magnetized components, interposing their respective isolation layers, and are electrically connected by electrode regions of the isolation layers.

This provides a thermoelectric device for easy positioning and bonding processes.

### [12] Specific Thermoelectric Materials

The thermoelectric device described in [11], wherein the thermoelectric material of the first thermoelectric stack is a magnetic material mainly composed of at least one material selected from the group consisting of Sm-Co alloy, Co₂MnGa alloy, Co₂Mn (Al, Si) alloy, Co, Fe—Ga alloy, Fe—Al alloy, FePt alloy, FePd alloy, Fe₃Sn₂ alloy, and iron nitride (Fe₄N), and the thermoelectric material of the second thermoelectric stack is a magnetic material mainly composed of at least one material selected from the group consisting of NdFeB alloy, MnGa alloy, Fe, and Co—Gd alloy.

In this manner, the thermoelectric materials suitable for constructing the thermoelectric devices described in [11] are identified.

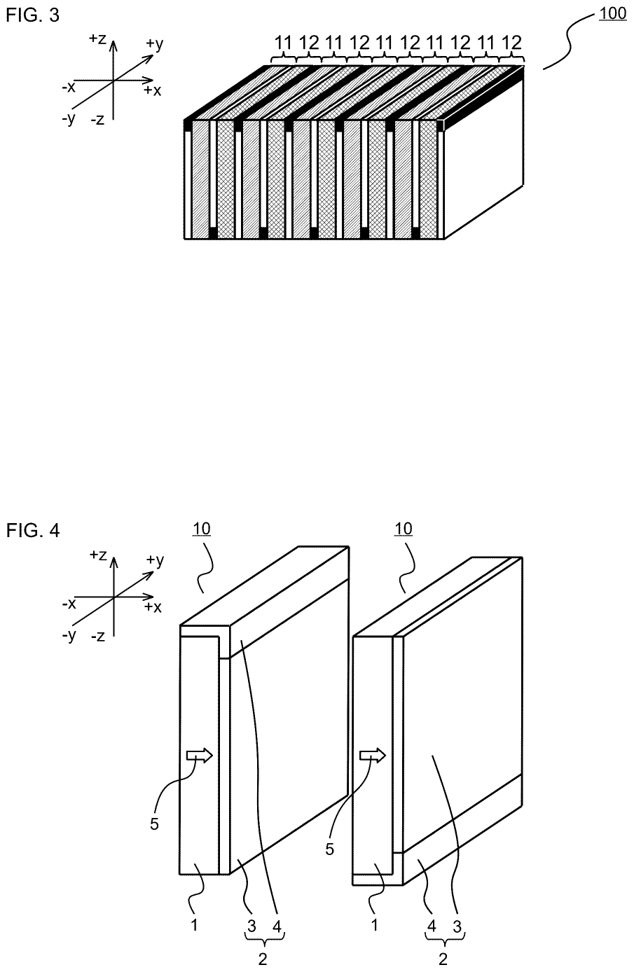

### [13] Transverse Thermoelectric Devices Connected in Series Due to Magnetic Force of Magnetization Components (FIG. 2, FIG. 3)

A representative embodiment disclosed in this application is a thermoelectric device in which one or more first thermoelectric material layers (1-2) having positive transverse thermoelectric power and one or more second thermoelectric material layers (1-1) having negative transverse thermoelectric power are alternately stacked with an isolation layer (2-1, 2-2) interposed therebetween, and has the following configuration.

the first and second thermoelectric material layers have magnetization components (5-1, 5-2) in the same direction perpendicular to the plane in which they are stacked, and the isolation layer comprises an insulation region (3-1, 3-2) that electrically insulates the first and second thermoelectric material layers that are in close contact with each other due to the magnetic force of the magnetization component, and an electrode region (4-2, 4-3) that conducts the first and second thermoelectric material layers together, and the electrode regions (4-1 and 4-2, 4-2 and 4-3) in contact with both surfaces of the first and second thermoelectric material layers are arranged at positions spaced apart from each other in a direction perpendicular to both the stacking direction of the thermoelectric material layers and the direction in which a temperature gradient is applied.

This provides a thermoelectric device for easy positioning and bonding processes. The positions spaced apart in a direction perpendicular to both the stacking direction and the direction in which the temperature gradient is applied are positions where the potential difference (electromotive force) caused by the driving electric field generated by the temperature gradient and remanent magnetization is maximum. Here, each electrode region may be composed of a plurality of electrode regions arranged at positions with approximately the same potential.

### [14] Electrode Region Extends to Side Surface of Thermoelectric Material Layer (FIG. 4, FIG. 5)

The thermoelectric device described in [13], wherein the isolation layer extends from an end of the surface to be stacked to the side surface of the thermoelectric material layer and has the electrode region in the extended region.

This allows the stress due to the magnetic force to be applied directly to the interface between the electrode region and the thermoelectric material layer, resulting in good contact electrical conductivity. Furthermore, the degree of freedom in the electrode formation and wiring process can be increased. Furthermore, by forming electrode regions (4) at the ends of thermoelectric material layer (1) (for example, FIG. 5), the entire thermoelectric material layer can be configured to contribute to thermoelectric conversion.

### [15] Easy Attachment and Removal by Magnetic Adhesion

The thermoelectric device described in any one of [13] to [15], wherein the first thermoelectric material layer and the second thermoelectric material layer adjacent to each other are removably stacked with the isolation layer interposed therebetween due to the magnetic force of the magnetization component.

This facilitates the positioning and bonding process, and allows for flexible response, such as adjusting the number of thermoelectric stacks to be stacked in accordance with the size of the object to be installed at the installation site.

[16] Three-Dimensional Structure Where Thermoelectric Material Layer Engages with Electrode (FIG. 4)

The thermoelectric device described in any one of [13] to [15], wherein the first and second thermoelectric material layers have a three-dimensional shape that engages with the isolation layer on at least one side that is in contact with the electrode region of the isolation layer.

This allows the thermoelectric material layer and the electrodes to be positioned in a self-aligned manner, making the wiring process even easier.

### [17] Specific Thermoelectric Materials

The thermoelectric device described in any one of [13] to [16], wherein the first thermoelectric material is a magnetic material mainly composed of at least one material selected from the group consisting of Sm-Co alloy, Co₂MnGa alloy, Co₂Mn (Al, Si) alloy, Co, Fe—Ga alloy, Fe—Al alloy, FePt alloy, FePd alloy, Fe₃Sn₂ alloy, and iron nitride (Fe₄N), and the second thermoelectric material is a magnetic material mainly composed of at least one material selected from the group consisting of NdFeB alloy, MnGa alloy, Fe, and Co—Gd alloy.

In this manner, the thermoelectric materials suitable for constructing the thermoelectric devices described in [13] through [16] are identified.

### [18] Tilted Stack

The thermoelectric device described in any one of [13] to [16], wherein at least one of the first and second thermoelectric material layers is a stack comprising a plurality of thermoelectric material layers that are different from each other.

This makes it possible to use a transverse thermoelectric material in which p-type and n-type thermoelectric materials are alternately layered with a tilt as the thermoelectric material layer. The “tilted stack” described above is a multilayer structure formed by stacking two or more types of thermoelectric material layers (the “unit thermoelectric material layers” described above), and the “stack” referred to here is different from the “stack” referred to in [13].

### 2. Details of the Embodiments

The embodiments will now be described in further detail.

### [First Embodiment]

FIG. 1 is an explanatory diagram schematically illustrating a basic configuration of thermoelectric stack 10 according to the present invention. Thermoelectric stack 10 comprises thermoelectric material layer 1 and isolation layer 2. Isolation layer 2 is stacked on one of the two opposing sides of thermoelectric material layer 1 (on the +x side of the yz plane in FIG. 1). Thermoelectric material layer 1 has magnetization component 5 perpendicular to the two planes (x-axis direction). Isolation layer 2 comprises, in the plane in contact with thermoelectric material layers 1 when stacked, insulation region 3 that insulates two adjacent thermoelectric material layers 1 and electrode region 4 that electrically connects them.

This provides thermoelectric stack 10 for easy positioning and bonding processes for constructing a thermoelectric device. The two thermoelectric material layers 1 are firmly adhered with isolation layer 2 interposed therebetween due to the magnetic force of the magnetization component perpendicular to the stacking plane, and are electrically connected at electrode region 4 which is part of isolation layer 2. This makes alignment easy, does not require a bonding process, and furthermore, wiring only needs to be done at both ends after bonding. Thus, for example, when installing a thermoelectric device, the number of thermoelectric stacks 10 to be stacked can be adjusted according to the size of the object, even at the site of installation.

FIG. 2 is an explanatory diagram schematically illustrating an operation principle of a thermoelectric device according to the present invention. As described above, thermoelectric stack 1 of the present invention has a magnetization component in the direction perpendicular to the stacking plane, so if aligned in the same direction, they can be bonded due to the magnetic force. FIG. 2 shows another thermoelectric stack 11 being stacked on the other side of thermoelectric stack 12 with insulation region 3-2 and electrode region 4-3 in isolation layer 2-2 on one side. Thermoelectric stack 11 and thermoelectric stack 12 have magnetization components 5-1 and 5-2 in the same direction perpendicular to the plane in which they are stacked, and are bonded together due to the magnetic forces in the left-right direction of the paper. When viewed from the thermoelectric stack 12, there is isolation layer 2-1 on the side on which another thermoelectric stack 11 is stacked, and when the thermoelectric stack 11 is brought into close contact due to the magnetic force, they are connected so as to be electrically insulated in insulation region 3-1 and electrically conductive in electrode region 4-2.

In FIG. 2, when thermoelectric stacks 11 and 12 are constructed using thermoelectric materials with positive and negative transverse thermoelectric power, respectively, the electromotive forces of thermoelectric stacks 11 and 12 are integrated through electrical series connection, making it possible to output a high voltage. If the direction of temperature gradient 30 is perpendicular to the plane of the paper and is from the front to the back as shown in FIG. 2, in thermoelectric stack 11 with positive transverse thermoelectric power, driving electric field E_{ANE} 20-1 is generated in the upward direction from below the paper as the cross product component of temperature gradient 30 and the magnetic force of magnetization component 5-1. The ratio of the potential gradient and the temperature gradient that result from the bottom to the top of the paper in the open-circuit voltage state is defined as the anomalous Nernst coefficient S_{ANE}. If thermoelectric stack 12 has a negative anomalous Nernst coefficient S_{ANE} with an opposite sign to that of thermoelectric stack 11 and is considered to be a thermoelectric stack with so-called negative transverse thermoelectric power, then in thermoelectric stack 12, driving electric field E_{ANE} 20 is generated in the downward direction from the top of the paper as the cross product component of temperature gradient 30 and the magnetic force of magnetization component 5-2.

Electrode regions 4-1 and 4-2 in contact with both sides of thermoelectric material layer 1-1, and electrode regions 4-2 and 4-3 in contact with both sides of thermoelectric material layer 1-2, are arranged in each thermoelectric material layer at positions spaced apart in a direction perpendicular to both the stacking direction and the direction in which the temperature gradient 30 is applied. It is most suitable to place them at the two most distant ends. Driving electric field E_{ANE} 20-2 is generated in the direction perpendicular to temperature gradient 30 and magnetization component 5-2, and the potential difference between both ends is maximized, so that the maximum value of the generated electromotive force can be extracted. Electrode regions 4-2 and 4-3 are arranged at positions with approximately the same potential, and may be divided into a plurality of electrode regions.

As described above, thermoelectric stacks 11 and 12 are insulated in insulation region 3-2 and conductive in electrode region 4-2, so they are connected in series between electrodes 4-3 and 4-1, and the sum of the potential difference due to the driving electric field E_{ANE} 20-2 and the potential difference due to the driving electric field E_{ANE} 20-1 is output. In this way, by alternately bringing into close contact materials with opposite signs of the anomalous Nernst coefficients S_{ANE} with each other due to the magnetic force while maintaining electrical insulation, and then electrically connecting them in series, it is possible to obtain a high-density transverse thermoelectric module.

The thermoelectric element of the present invention is highly efficient in terms of volume utilization as well. In conventional π-type thermoelectric devices, p-type and n-type thermoelectric materials are each formed into columns and arranged apart from each other. Since the columnar thermoelectric materials are spaced apart by alignment, the gaps form a volume that does not directly contribute to thermoelectric conversion.

In the thermoelectric element according the present invention, when viewed from the vector direction of temperature gradient 30, the area through which a heat flow passes consists of only thermoelectric material layer 1 and isolation layer 2. Isolation layer 2 only needs to be insulating when it is brought into close contact with the magnetic force, and since the potential difference is low, it does not need to be thick enough to take into consideration the dielectric strength voltage, and a thin film-like thickness is sufficient. Therefore, thermoelectric material layer 1 occupies most of the area through which the heat flow passes, allowing the majority of the heat flow to contribute directly to thermoelectric conversion. Even in the direction from the front to the back of the vector of temperature gradient 30, no electrodes or substrates are required, and a structure occupied only by thermoelectric material layer 1 can be formed. In this way, there is very little material other than the thermoelectric material on the surface through which the heat flow passes, and also in the path in the direction through which the heat flow passes, and the thermoelectric element of the present invention can be said to be highly efficient in terms of volume utilization as well.

### [Second Embodiment]

FIG. 2 shows a simple thermoelectric device in which a single thermoelectric stack 11 and a single thermoelectric stack 12 are stacked, but an arbitrary number of layers may be stacked.

FIG. 3 is an explanatory diagram illustrating an example configuration of thermoelectric device 100 as an embodiment of the present invention. Thermoelectric device 100 is formed by five thermoelectric stack 11 and five thermoelectric stack 12 stacked alternately. In thermoelectric device 100, thermoelectric material layers having positive transverse thermoelectric power contained in thermoelectric stack 11 and thermoelectric material layers having negative transverse thermoelectric power contained in thermoelectric stack 12 are alternately stacked, each having an isolation layer interposed therebetween. The thermoelectric material layers of thermoelectric stacks 11 and 12 have magnetization components in the same direction perpendicular to the plane in which they are stacked (x-axis direction), and the adjacent thermoelectric material layers that are in close contact with each other due to the magnetic force of the magnetization components thereof are insulated in the insulation regions by the isolation layer and electrically conducted in the electrode regions by the isolation layer. This magnetization component not only brings the thermoelectric stack into close contact, but also generates a driving electric field E_{ANE} in the thermoelectric material layer due to the anomalous Nernst effect. That is, when a temperature gradient is applied in the y-axis direction, a driving electric field E_{ANE} due to the anomalous Nernst effect is generated in each thermoelectric material layer in opposite directions between adjacent thermoelectric material layers. The electrode regions that electrically connect adjacent thermoelectric material layers are alternately located at the most distant positions in the direction perpendicular to both the temperature gradient and the stacking direction (z-axis direction), so that the potential differences that occur alternately in opposite directions can be connected in series, and the large potential difference integrated across both ends can be output as electromotive force.

Since thermoelectric stacks 11 and 12 have magnetization components in the same direction in the stacking direction, they are closely attached and electrically connected due to the magnetic force simply by arranging them adjacent to each other, so the positioning and joining processes in thermoelectric device 100 are extremely easy.

### [Third Embodiment]

In the first and second embodiments, as mainly illustrated in FIGS. 1 to 3, an embodiment is shown in which thermoelectric material layer 1 (1-1, 1-2) and isolation layer 2 (2-1, 2-2) overlap with the same area when viewed from the x-axis direction. In this configuration, as described above, no components are inserted in series in the path along which heat flows through the thermoelectric material layer, and only thermoelectric material layer 1 and isolation layer 2 are present in parallel. Therefore, the applied temperature gradient is expected to be applied to thermoelectric material layer 1 with almost no waste, contributing to thermoelectric conversion. The structure of the electrode region 4 is not limited to that described; part or all of electrode region 4 may alternatively extend to the side wall of thermoelectric material layer 1 and may even be formed apart from insulation region 3 of isolation layer 2.

FIGS. 4 and 5 are explanatory drawings illustrating variations of the electrode region. As shown in FIG. 4, a part of electrode region 4 may extend along a side (z-side or-z-side) surface of thermoelectric material layer 1. This extension to the side surface can construct the entire thermoelectric material to contribute to thermoelectric conversion, which provides ideal thermoelectromotive force. For example, as shown in FIG. 5, by forming electrode region 4 at one end of thermoelectric material layer 1, all electromotive forces generated anywhere from one end of thermoelectric material layer 1 to the other can be extracted by flowing them into electrode regions 4.

The electrical connection between the thermoelectric material layers 1 of adjacent thermoelectric stacks 10 may be formed at the contact surfaces as in FIG. 1, or a separate wiring, for example, a crimped wiring made of indium, may be added. Alternatively, the entire electrode region 4 may be formed on the side surface of thermoelectric material layer 1, as shown in FIG. 5. In this case, after thermoelectric stacks 10 consisting of isolation layer 2 having only insulation region 3 and thermoelectric material layer 1 are stacked in close contact with each other due to their mutual remanent magnetization, a crimped wiring made of, for example, indium is formed to electrically connect adjacent thermoelectric material layers 1 so that a series circuit is formed overall.

### [Fourth Embodiment]

FIG. 6 is an explanatory drawing illustrating another electrode structure. In the thermoelectric stack according to the present embodiment, thermoelectric material layer 1 has a three-dimensional shape that engages with isolation layer 2 on the surface in contact with isolation layer 2. This allows the thermoelectric material layer and the electrodes to be positioned in a self-aligned manner, making the wiring process even easier. FIG. 6 is an example. The left thermoelectric material layer 1 has notches 41 and 42 formed therein. Isolation layer 2, which is stacked from the right side of the drawing, has a thicker electrode region 4 than insulation region 3. When thermoelectric material layer 1 and isolation layer 2 are bonded together, electrode region 4 of the isolation layer engage with notches 41 and 42 of thermoelectric material layer 1. The size of electrode region 4 protruding beyond insulation region 3 toward thermoelectric material layer 1 is preferably designed so that it fits snugly into notches 41 and 42. This also facilitates easy alignment of the thermoelectric material layer and the isolation layer. Furthermore, as the contact area between the thermoelectric material layer and electrode region 4 increases, the contact resistance also decreases. In this example, a simple notch is used, but by adopting a shape that increases the contact area, it is possible to further reduce the electrical contact resistance.

As illustrated in FIG. 6, electrode region 4 can be configured to protrude on both sides beyond insulation region 3, and to engage with another thermoelectric material layer 1 that is in close contact with the opposite side (further to the right in FIG. 6). Furthermore, as shown in the rightmost example of FIG. 6, thermoelectric material layer 1 may have notches 43 and 44, and notches 45 and 46 on both sides to be stacked.

### [Fifth Embodiment]

A variety of layers that utilize various transverse thermoelectric conversion phenomena can be adopted as thermoelectric material layer 1. For example, transverse thermoelectric materials such as magnetic materials that exhibit the anomalous Nernst effect or the spin Seebeck effect, and gonio-polar materials with anisotropic Seebeck coefficients can be used. Furthermore, a geometrically guided transverse thermoelectric material can be employed by alternately stacking p-type and n-type Seebeck materials obliquely to the temperature gradient direction. Various transverse thermoelectric conversion phenomena can be superimposed by such composite materials to enhance the output.

FIG. 9 is an explanatory diagram illustrating another example configuration of a thermoelectric device according to the present invention. Thermoelectric stacks 11 and 12 are respectively composed of thermoelectric material layer 1-1 and isolation layer 2-1, and thermoelectric material layer 1-2 and isolation layer 2-2, which are in close contact with each other to form the thermoelectric device, similar to the second embodiment. Thermoelectric material layers 1-1 and 1-2 are each formed by alternately stacking two types of thermoelectric material layers 1a and 1b, and 1c and 1d, respectively, with the stacking direction tilted from temperature gradient 30. For example, by using p-type and n-type thermoelectric materials for the thermoelectric material layers 1a and 1b, and 1c and 1d, respectively, the layers can function as transverse thermoelectric material layers, and the sign of the driving electric field can be reversed by reversing the tilt angle with respect to the temperature gradient (y-axis direction). Furthermore, thermoelectric material layers 1a or 1b, 1c or 1d may be made of magnetic materials to generate magnetization components 5-1 and 5-2.

### EXAMPLES

As an example of a thermoelectric device in which stacks can be connected due to the magnetic force, a transverse thermoelectric module was fabricated using two types of permanent magnets with different signs of anomalous Nernst effect, which is one type of transverse thermoelectric power, and its characteristics were evaluated. The operation principle of the transverse thermoelectric module of this Example is the same as that described in the second embodiment.

### [Module Processing]

As materials with an anomalous Nernst coefficient S_{ANE} of the opposite sign, the following were prepared: a samarium cobalt (SmCo₅) magnet with a diameter of 20 mm and a thickness of 0.5 mm (YX24, manufactured by Magfine Corporation), and a neodymium iron boron (Nd₂Fe₁₄B) magnet with a diameter of 20 mm and a thickness of 0.5 mm (N35, manufactured by Magfine Corporation, with NiCuNi plating), both of which were disk-shaped and had an easy axis of magnetization perpendicular to the surface. The SmCo₅ magnet has a positive anomalous Nernst coefficient S_{ANE}, and the Nd₂Fe₁₄B magnet has a negative anomalous Nernst coefficient S_{ANE}.

Twelve disk-shaped SmCo₅ magnets and twelve Nd₂Fe₁₄B magnets were stacked alternately in the same magnetization direction to produce a total of 24 stacks. When stacking, a paper towel (manufactured by AS ONE Corporation) was placed on top of the bottom magnet as an insulation layer, and then instant adhesive (Aron Alpha Tough Power, manufactured by Toagosei Co., Ltd.) was applied before the next magnet (a magnet with an anomalous Nernst coefficient S_{ANE} of the opposite sign) was placed on top to secure the discs together.

The resulting stack was cut into a rectangular parallelepiped shape using a diamond wire saw (DWS100 manufactured by EiResearch Co., Ltd.). Furthermore, the side surfaces of the material were crimped and wired with indium (manufactured by The Nilaco Corporation) to form a circuit in which SmCo₅ magnets and Nd₂Fe₁₄B magnets were alternately connected in series, completing a transverse thermoelectric module.

Two copper wires (manufactured by The Nilaco Corporation) were connected to both ends of the electrical circuit of the completed transverse thermoelectric module, and the side surfaces of the module, except the contact and contact-facing surfaces, were secured with a heat dissipation adhesive (COM-G52 manufactured by Com⋅institute Inc).

The area ratio of the SmCo₅ and Nd₂Fe₁₄B magnets, which are thermoelectric materials, to the heat-receiving surface of the module exceeds 81%, which is an unprecedented occupancy density compared to conventional π-type thermoelectric modules.

In the transverse thermoelectric module of this Example, a separator having the insulation region and the electrode region can be formed by, for example, the following film-forming process, coating process, or attaching process.

Film-forming process: A film of metal such as aluminum (Al) is deposited on a magnet, which is a thermoelectric material. The electrode region is covered with an antioxidant film such as resist, and the rest of the area is oxidized to form an insulation region. The antioxidant film is then removed with an organic solvent, etc.

Coating process: Silver paste or indium is applied to the electrode region, and high heat-resistant adhesive or Aron ceramic is applied to the insulation region.

Attaching process: Adhesive tape with a conductive region is attached. Adhesive tape with a conductive region is, for example, an adhesive tape that has a conductive circuit portion that penetrates the surface and an insulating portion other than that, and becomes electrically conductive when attached to a magnet.

### [Measurement of Power Generation Performance]

The power generation performance of the transverse thermoelectric module was evaluated by applying a temperature difference ΔT to both sides of the module and measuring the current-voltage characteristics of the two copper wires using four-terminal measurements. That is, the voltage V was measured by sweeping the load current I_{load}, with one copper wire defined as a positive voltage (V+) and a negative current (I−), and the other as a negative voltage (V−) and a positive current (I+). The power generation output P is expressed as the product of the load current I_{load} and the voltage V.

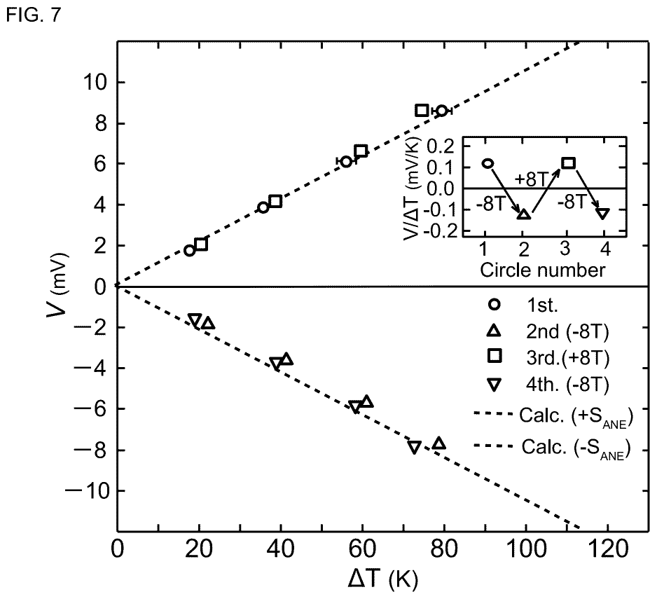

FIG. 7 is a graph showing the measurement results of the power generation behavior of the thermoelectric material fabricated as Example. That is, to confirm that the output generated by the temperature difference ΔT is due to the anomalous Nernst effect, the open-circuit voltage V was measured by the following procedure.

Using a pulsed magnetic field generator (manufactured by Toei Scientific Industrial Co., Ltd.), a voltage of +8T was applied to the easy axis of magnetization of the SmCo₅ magnet and the Nd₂Fe₁₄B magnet to magnetize them, and in this state a temperature difference ΔT was applied to measure the open-circuit voltage V (Circle number 1). Next, the magnetization of the SmCo₅ and Nd₂Fe₁₄B magnets was reversed in turn three times at −8T, +8T, and −8T using the same procedure, and the open-circuit voltage was measured each time (Circle numbers 2 to 4). The inset shows the sign reversal of the anomalous Nernst voltage associated with magnetization reversal, converted to V/ΔT. In FIG. 7, the horizontal axis represents the applied temperature difference ΔT (K), and the vertical axis represents the electromotive force V (mV) of the fabricated transverse thermoelectric module. FIG. 7 also shows the anomalous Nernst voltage calculated from the anomalous Nernst coefficient S_{ANE}, temperature difference, dimensions, and number of layers for each of the SmCo₅ and Nd₂Fe₁₄B magnets, as calculated values (Calc.) as dashed lines. The measurement results in FIG. 7 confirm that the experimentally obtained open-circuit voltage V is due to the anomalous Nernst effect, since the open-circuit voltage shows a symmetrical behavior depending on the magnetization direction and is in good agreement with the calculated value of the anomalous Nernst voltage.

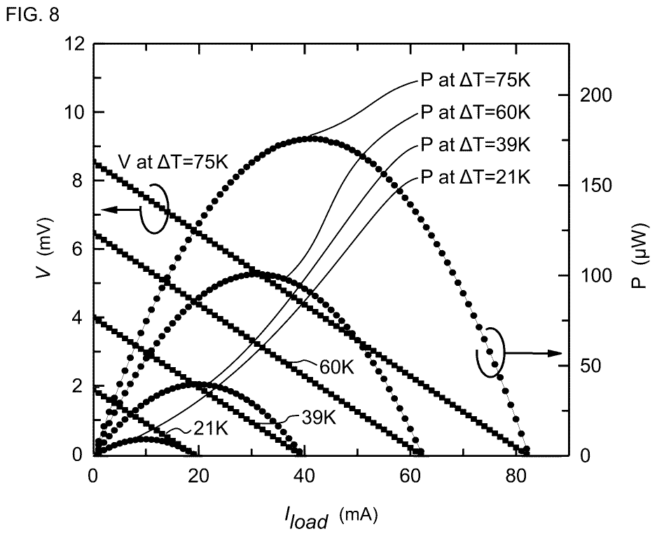

FIG. 8 is a graph showing the power generation performance of the transverse thermoelectric module fabricated as Example. The four temperature differences ΔT=21K, 39K, 60K, 75K are used as parameters, and the load current I_{load} (mA) swept while applying each temperature difference ΔT is shown on the horizontal axis, the measured voltage V (mV) on the left vertical axis, and the generated power P (μW), which is the product of the voltage V (mV) and the load current I_{load} (mA), on the right vertical axis. As a result of the measurements, a maximum power generation of 177 μW was measured at a temperature difference ΔT=75 K. This generated power has a power generation density of 65 μW/cm² per unit contact area.

The present invention made by the present inventors has been specifically described above based on the embodiments, but obviously, the present invention is not limited thereto and can be modified in various ways without departing from the spirit of the present invention.

### EXPLANATION OF SIGN

1, 1-1, 1-2 Thermoelectric material
2, 2-1, 2 -2 Isolation layer
3, 3-1, 3-2 Insulation region
4, 4-1, 4-2, 4-3 Electrode region
5, 5-1, 5-2 Magnetization component perpendicular to stacking plane
10, 11, 12 Thermoelectric stack
20-1, 20-2 Driving electric field
30 Temperature gradient
41-46 Notch in thermoelectric material layer
100 Thermoelectric device

1. A thermoelectric stack comprising a thermoelectric material layer having a first surface and a second surface opposite each other and an isolation layer stacked on the first surface of the thermoelectric material layer, wherein
the thermoelectric material layer has a magnetization component perpendicular to the first surface and the second surface; and
the isolation layer comprises an insulation region and an electrode region, each of which is in close contact with the thermoelectric material layer and a thermoelectric material layer of a second thermoelectric stack, and when the second thermoelectric stack is stacked on the surface opposite to the surface on which the thermoelectric material layer is to be stacked, the insulation region that electrically insulates the thermoelectric material layer from a thermoelectric material layer of the second thermoelectric stack and the electrode region that electrically connects the thermoelectric material layer to the thermoelectric material layer of the second thermoelectric stack.

2. The thermoelectric stack according to claim 1, wherein the electrode region is made of a material different from that of the thermoelectric material layer and that of the thermoelectric material layer of the other thermoelectric stack, and contacts the two thermoelectric material layers.

3. The thermoelectric stack according to claim 1, wherein the isolation layer extends from an end of the first surface to a side surface of the thermoelectric material layer, and has the electrode region in the extended region.

4. The thermoelectric stack according to claim 1, wherein the electrode region of the isolation layer is interposed between the thermoelectric material layer and the thermoelectric material layer of the second thermoelectric stack when the second thermoelectric stack is stacked on the surface opposite the surface on which the thermoelectric material layer is stacked.

5. The thermoelectric stack according to claim 1, wherein the thermoelectric material layer has a three-dimensional shape that engages with the isolation layer on a surface in contact with the isolation layer.

6. The thermoelectric stack according to claim 1, wherein the isolation layer is a first isolation layer, the insulation region is a first insulation region, and the electrode region is a first electrode region,
the thermoelectric stack has a second isolation layer stacked on the second surface, and
the second isolation layer comprises, when a second thermoelectric stack is stacked due to the magnetic force of the magnetization component on the surface opposite to the surface on which the thermoelectric material layer is to be stacked, a second insulation region that electrically insulates the thermoelectric material layer from a thermoelectric material layer of the second thermoelectric stack and a second electrode region that electrically connects the thermoelectric material layer to a thermoelectric material layer of the second thermoelectric stack.

7. The thermoelectric stack according to claim 6, wherein
the first electrode region and the second electrode region are positioned apart from each other in the plane of the first and second surfaces when the first and second surfaces are viewed in plan view.

8. The thermoelectric stack according to claim 4, wherein
the insulation region is adhesive.

9. The thermoelectric stack according to claim 8, wherein
the insulation region is separatable.

10. The thermoelectric stack according to claim 1, wherein the thermoelectric material layer comprises two or more thermoelectric materials.

11. The thermoelectric stack according to claim 10, wherein
the thermoelectric material layer is formed by stacking unit thermoelectric material layers of the two or more thermoelectric materials.

12. A thermoelectric device, comprising a plurality of thermoelectric stacks according to claim 1, wherein the plurality of thermoelectric stacks include:
one or more first thermoelectric stacks, the thermoelectric material layers of which have positive transverse thermoelectric power, and
one or more second thermoelectric stacks, the thermoelectric material layers of which have negative transverse thermoelectric power,
the first and second thermoelectric stacks being alternately brought into close contact with each other due to the magnetic force of their magnetized components, interposing their respective isolation layers, and are electrically connected by electrode regions of the isolation layers.

13. The thermoelectric device according to claim 12, wherein
the thermoelectric material of the first thermoelectric stack is a magnetic material mainly composed of at least one material selected from the group consisting of Sm—Co alloy, Co₂MnGa alloy, Co₂Mn (Al, Si) alloy, Co, Fe—Ga alloy, Fe—Al alloy, FePt alloy, FePd alloy, Fe₃Sn₂ alloy, and iron nitride (Fe₄N), and
the thermoelectric material of the second thermoelectric stack is a magnetic material mainly composed of at least one material selected from the group consisting of NdFeB alloy, MnGa alloy, Fe, and Co—Gd alloy.

14. A thermoelectric device in which one or more first thermoelectric material layers having positive transverse thermoelectric power and one or more second thermoelectric material layers having negative transverse thermoelectric power are alternately stacked with an isolation layer interposed therebetween, wherein
the first and second thermoelectric material layers have magnetization components in the same direction perpendicular to the plane in which they are stacked,
the isolation layer comprises an insulation region that electrically insulates the first and second thermoelectric material layers that are in close contact with each other due to the magnetic force of the magnetization component, and an electrode region that conducts the first and second thermoelectric material layers together, and
the electrode regions in contact with both surfaces of the first and second thermoelectric material layers are arranged at positions spaced apart from each other in a direction perpendicular to both the stacking direction of the thermoelectric material layers and the direction in which a temperature gradient is applied.

15. The thermoelectric device according to claim 14, wherein the isolation layer extends from an end of the surface to be stacked to the side surface of the thermoelectric material layer and has the electrode region in the extended region.

16. The thermoelectric device according to claim 14, wherein
the first thermoelectric material layer and the second thermoelectric material layer adjacent to each other are removably stacked with the isolation layer interposed therebetween due to the magnetic force of the magnetization component.

17. The thermoelectric device according to claim 14, wherein
the first and second thermoelectric material layers have a three-dimensional shape that engages with the isolation layer on at least one side that is in contact with the electrode region of the isolation layer.

18. The thermoelectric device according to claim 14, wherein
the first thermoelectric material is a magnetic material mainly composed of at least one material selected from the group consisting of Sm—Co alloy, Co₂MnGa alloy, Co₂Mn (Al, Si) alloy, Co, Fe—Ga alloy, Fe—Al alloy, FePt alloy, FePd alloy, Fe₃Sn₂ alloy, and iron nitride (Fe₄N), and
the second thermoelectric material is a magnetic material mainly composed of at least one material selected from the group consisting of NdFeB alloy, MnGa alloy, Fe, and Co—Gd alloy.

19. The thermoelectric device according to claim 14, wherein
at least one of the first and second thermoelectric material layers is a stack comprising a plurality of thermoelectric material layers that are different from each other.
